(19) United States
(12) Patent Application Publication
(10) Pub. No.: US 2025/0112054 A1
(43) Pub. Date: Apr. 3, 2025

(54) CARBON REPLENISHMENT OF SILICON-CONTAINING MATERIALS TO REDUCE THICKNESS LOSS

(71) Applicant: Applied Materials, Inc., Santa Clara, CA (US)

(72) Inventors: Yuriy Shusterman, Ballston Lake, NY (US); Sean Reidy, Clifton Park, NY (US); Sai Hooi Yeong, Cupertino, CA (US); Lisa Megan McGill, Hillsboro, OR (US); Benjamin Colombeau, San Jose, CA (US); Andre P. Labonte, Mechanicville, NY (US); Veeraraghavan S. Basker, Fremont, CA (US); Balasubramanian Pranatharthiharan, San Jose, CA (US)

(73) Assignee: Applied Materials, Inc., Santa Clara, CA (US)

(21) Appl. No.: 18/894,665

(22) Filed: Sep. 24, 2024

Related U.S. Application Data
(60) Provisional application No. 63/542,109, filed on Oct. 3, 2023.
(60) Provisional application No. 63/669,136, filed on Jul. 9, 2024.

(51) Int. Cl. H01L 21/3065; H01L 21/02; H01L 21/26; H01L 21/311

(52) U.S. Cl. CPC H01L 21/3065; H01L 21/02057; H01L 21/26; H01L 21/31116

(57) ABSTRACT

Exemplary methods of semiconductor processing may include providing an etchant precursor to a processing region of a semiconductor processing chamber. A structure may be disposed within the processing region. The structure may include a first silicon-containing material. The structure may include a second silicon-containing material, an oxygen-containing material, or both. The methods may include contacting the structure with the etchant precursor. The contacting with the etchant precursor may etch at least a portion of the second silicon-containing material or the oxygen-containing material from the structure. The methods may include providing a carbon-containing precursor to the processing region of the semiconductor processing chamber. The methods may include contacting the structure with the carbon-containing precursor. The contacting with the carbon-containing precursor may replenish carbon in the first silicon-containing material.

### CROSS-REFERENCE TO RELATED APPLICATION

This application claims the benefit of, and priority to U.S. Provisional Application Ser. No. 63/542,109, filed Oct. 3, 2023, and U.S. Provisional Application Ser. No. 63/669,136, filed Jul. 9, 2024, which are hereby incorporated by reference in their entirety for all purposes.

### TECHNICAL FIELD

The present technology relates to methods and systems for semiconductor processing. More specifically, the present technology relates to systems and methods for replenishing carbon in silicon-containing materials after etching operations to prevent thickness loss of the silicon-containing materials during subsequent operations.

### BACKGROUND

Integrated circuits are made possible by processes which produce intricately patterned material layers on substrate surfaces. Producing patterned material on a substrate requires controlled methods for forming and removing material. As device sizes continue to reduce, film characteristics may lead to larger impacts on device performance. Materials used to form layers of materials may affect operational characteristics of the devices produced. As material thicknesses continue to reduce, as-deposited characteristics of the films may have a greater impact on device performance.

Thus, there is a need for improved systems and methods that can be used to produce high quality devices and structures. These and other needs are addressed by the present technology.

### SUMMARY

Exemplary methods of semiconductor processing may include providing an etchant precursor to a processing region of a semiconductor processing chamber. A structure may be disposed within the processing region. The structure may include a first silicon-containing material. The structure may include a second silicon-containing material, an oxygen-containing material, or both. The methods may include contacting the structure with the etchant precursor. The contacting with the etchant precursor may etch at least a portion of the second silicon-containing material or the oxygen-containing material from the structure. The methods may include providing a carbon-containing precursor to the processing region of the semiconductor processing chamber. The methods may include contacting the structure with the carbon-containing precursor. The contacting with the carbon-containing precursor may replenish carbon in the first silicon-containing material.

In some embodiments, the second silicon-containing material may be or include a silicon-and-oxygen-containing material or a silicon-and-germanium-containing material. The first silicon-containing material may be or include a silicon-and-carbon-containing material. The etchant precursor may be or include a halogen-containing precursor. Contacting the structure with the carbon-containing precursor may increase carbon in the first silicon-containing material by greater than or about 0.1 at. %. The carbon-containing precursor may be or include hexamethyldisilazane (HMDS), tetramethyldisilazane (TMDS), trimethylchlorosilane (TMCS), dimethyldichlorosilane (DMDCS), methyltrichlorosilane (MTCS), trimethylmethoxysilane (TMMS) (CH₃—O—Si—(CH₃)₃), dimethyldimethoxysilane (DMDMS) ((CH₃)₂—Si—(OCH₃)₂), methyltrimethoxysilane (MTMS) ((CH₃—O)₃—Si—CH₃), phenyltrimethoxysilane (PTMOS) (C₆H₅—Si—(OCH₃)₃), phenyldimethylchlorosilane (PDMCS) (C₆H₅—Si(Cl)—(CH₃)₂), dimethylaminotrimethylsilane (DMATMS) ((CH₃)₂—N—Si—(CH₃)₃), or bis(dimethylamino)dimethylsilane (BDMADMS). The methods may include exposing the structure to ultraviolet (UV) radiation while contacting the structure with the carbon-containing precursor or subsequent to contacting the structure with the carbon-containing precursor. Contacting the structure with the carbon-containing precursor and exposing the structure to ultraviolet (UV) radiation may be performed simultaneously. The methods may include, subsequent to contacting the structure with the carbon-containing precursor, providing a cleaning agent to the processing region of the semiconductor processing chamber. The methods may include contacting the structure with the cleaning agent. The contacting with the cleaning agent may remove a residue from the structure. A temperature in the semiconductor processing chamber may be less than or about 500° C.

Some embodiments of the present technology may encompass semiconductor processing methods. The methods may include providing a first etchant precursor to a processing region of a semiconductor processing chamber, wherein a structure is disposed within the processing region. The structure may include alternating layers of a first silicon-containing material and a silicon-and-germanium-containing material. The structure may include a second silicon-containing material overlying and extending into one or more recesses defined by the alternating layers of the first silicon-containing material and the silicon-and-germanium-containing material. The methods may include contacting the structure with the first etchant precursor. The contacting with the first etchant precursor may etch through the alternating layers of the first silicon-containing material and the silicon-and-germanium-containing material. The methods may include providing a first carbon-containing precursor to the processing region of the semiconductor processing chamber. The methods may include contacting the structure with the first carbon-containing precursor. The contacting with the first carbon-containing precursor may replenish carbon in the second silicon-containing material. The methods may include providing a first cleaning agent to the processing region of the semiconductor processing chamber. The methods may include contacting the structure with the first cleaning agent. The contacting with the first cleaning agent may remove a first residue from the structure. The methods may include providing a second etchant precursor to the processing region of the semiconductor processing chamber. The methods may include contacting the structure with the second etchant precursor. The contacting may etch a portion of the silicon-and-germanium-containing material. The methods may include providing a silicon-containing precursor to the processing region. The methods may include contacting the structure with the silicon-containing precursor. The contacting may deposit a third silicon-containing material on the structure. The third silicon-containing material may extend into recesses defined by the etched portion of the silicon-and-germanium-containing material. The methods may include providing a third etchant precursor to the processing region of the semiconductor processing chamber. The methods may include contacting the structure with the third etchant precursor. The contacting may etch a portion of the third silicon-containing material. Subsequent to the contacting, the third silicon-containing material remaining may extend into recesses defined by the etched portion of the silicon-and-germanium-containing material. The methods may include providing a second carbon-containing precursor to the processing region of the semiconductor processing chamber. The methods may include contacting the structure with the second carbon-containing precursor. The contacting with the second carbon-containing precursor may replenish carbon in the third silicon-containing material. The methods may include providing a second cleaning agent to the processing region of the semiconductor processing chamber. The methods may include contacting the structure with the second cleaning agent. The contacting with the second cleaning agent may remove a second residue from the structure. The methods may include providing a fourth etchant precursor to the processing region of the semiconductor processing chamber. The methods may include contacting the structure with the fourth etchant precursor. The contacting with the fourth etchant precursor may remove a dummy oxide material from the structure. The methods may include providing a third carbon-containing precursor to the processing region of the semiconductor processing chamber. The methods may include contacting the structure with the third carbon-containing precursor. The contacting with the third carbon-containing precursor may replenish carbon in the second silicon-containing material. The methods may include providing a fifth etchant precursor to the processing region of the semiconductor processing chamber. The methods may include contacting the structure with the fifth etchant precursor. The contacting with the fifth etchant precursor may remove the silicon-and-germanium-containing material from the structure. The methods may include providing a fourth carbon-containing precursor to the processing region of the semiconductor processing chamber. The methods may include contacting the structure with the fourth carbon-containing precursor. The contacting with the fourth carbon-containing precursor may replenish carbon in the second silicon-containing material, the third silicon-containing material, or both.

In some embodiments, one or more of the first carbon-containing precursor, the second carbon-containing precursor, the third carbon-containing precursor, and the fourth carbon-containing precursor may be the same carbon-containing precursor. The second silicon-containing material, the third silicon-containing material, or both may be characterized by a dielectric constant of less than or about 7.5. Contacting the structure with the first carbon-containing precursor, the second carbon-containing precursor, the third carbon-containing precursor, or the fourth carbon-containing precursor may prevent thickness loss of the second silicon-containing material, the third silicon-containing material, or both during subsequent operations. One or more of the first etchant precursor, the second etchant precursor, the third etchant precursor, or the fourth etchant precursor may be or include a hydrogen-containing precursor, a nitrogen-containing precursor, a helium-containing precursor, a halogen-containing precursor, or an oxygen-containing precursor. The methods may include depositing an epitaxial material on the structure prior to contacting the structure with the fourth etchant precursor.

Some embodiments of the present technology may encompass semiconductor processing systems. The systems may include a first semiconductor processing chamber. The first semiconductor processing chamber may be configured to flow an etchant precursor to a processing region of the first semiconductor processing chamber. A structure may be disposed within the processing region. The structure may include a first silicon-containing material. The structure may include a second silicon-containing material, an oxygen-containing material, or both. The first semiconductor processing chamber may be configured contact the structure with the etchant precursor. The contacting with the etchant precursor may etch at least a portion of the second silicon-containing material or the oxygen-containing material from the structure. The systems may include a second semiconductor processing chamber on the same mainframe as the first semiconductor processing chamber. The second semiconductor processing chamber may be configured to flow a carbon-containing precursor to a processing region of the second semiconductor processing chamber. The second semiconductor processing chamber may be configured to contact the structure with the carbon-containing precursor. The contacting with the carbon-containing precursor may replenish carbon in the first silicon-containing material.

In some embodiments, the systems may include a third semiconductor processing chamber on the same mainframe as the first semiconductor processing chamber and the second semiconductor processing chamber. The third semiconductor processing chamber may be configured to flow a cleaning agent to a processing region of the third semiconductor processing chamber. The third semiconductor processing chamber may be configured to contact the structure with the cleaning agent. Contacting with the cleaning agent may remove a residue from the structure. The systems may include a fourth semiconductor processing chamber on the same mainframe as the first semiconductor processing chamber, the second semiconductor processing chamber, and the third semiconductor processing chamber. The fourth semiconductor processing chamber may be configured to flow one or more deposition gases to a processing region of the fourth semiconductor processing chamber. The fourth semiconductor processing chamber may be configured to contact the structure with the one or more deposition gases. Contacting with the one or more deposition gases may deposit an epitaxial material on the structure. The systems may include one or more pre-treatment semiconductor processing chambers on the same mainframe as the first semiconductor processing chamber and the second semiconductor processing chamber. The one or more pre-treatment semiconductor processing chambers may be configured to etch a portion of the first silicon-containing material and the silicon-and-germanium-containing material, deposit the second silicon-containing material on the structure, and/or etch a portion of the second silicon-containing material.

Such technology may provide numerous benefits over conventional systems and techniques. For example, embodiments of the present technology may increase carbon concentrations in materials that have been carbon depleted which may increase resistance to subsequent etching operations, such as thermal, dry pre-cleans. The increased resistance may allow subsequent operations to be performed to structures with reduced or eliminated removal of the materials treated due to increased carbon concentrations. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma deposition system according to some embodiments of the present technology.

FIG. 3 shows operations in a semiconductor processing method according to some embodiments of the present technology.

FIGS. 4A-4C show cross-sectional views of structures being processed according to some embodiments of the present technology.

FIG. 5 shows operations in a semiconductor processing method according to some embodiments of the present technology.

FIGS. 6A-6I show cross-sectional views of structures being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As semiconductor device sizes continue to reduce, the constituent films included within a structure may affect device performance, as well as fabrication of other materials being included in the device. Additionally, as demand increases, throughput and queue times become a point of emphasis. Thus, a demand exists for high-quality materials and structures that may be formed both quickly and efficiently. However, in processes to form conformal low dielectric constant silicon-containing materials, such as in gate all around (GAA) applications, high conformality and low dielectric constant may result in poor resistance during subsequent etching operations. Due to the depletion of carbon in the silicon-containing materials during trimming and other removal operations, the silicon-containing material may be completely removed during etching operations, such as cleaning operations using wet etchants.

To further increase conformality and decrease dielectric constant, conventional technologies may change deposition precursors and may deposit alternative materials, such as silicon-oxygen-and-carbon-containing materials. Although these techniques may be effective in depositing high quality materials, the materials may be prone to complete removal during subsequent operations due to poor resistance to some etchant materials.

The present technology overcomes these issues by intermittently treating the silicon-containing material having high conformality and low dielectric constant. After some etching operations or ashing operations, such as spacer trimming, dummy gate removal, and/or channel release in GAA processing, the remaining silicon-containing material may be treated with a carbon-containing precursor during a carbon replenishment treatment and/or ultraviolet (UV) radiation. These treatments may return depleted carbon to the silicon-containing material, increasing the materials resistance to subsequent wet etching operations.

Although the remaining disclosure will routinely identify specific processes utilizing the disclosed technology, it will be readily understood that the systems and methods are equally applicable to other deposition and etching processes as may occur in the described chambers or any other chamber. Accordingly, the technology should not be considered to be so limited as for use with these specific deposition processes or chambers alone. The disclosure will discuss one set of possible chambers that may be used to perform processes according to embodiments of the present technology before additional variations and adjustments to this system according to embodiments of the present technology are described.

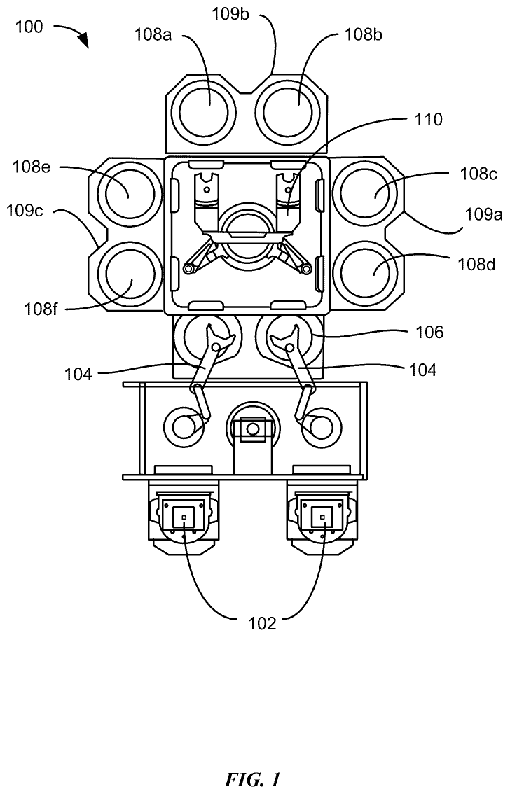

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the semiconductor processing chambers 108a-f, positioned in tandem sections 109a-c. A second robotic arm 110 may be used to transport the substrate wafers from the holding area 106 to the semiconductor processing chambers 108a-f and back. Each semiconductor processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The semiconductor processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

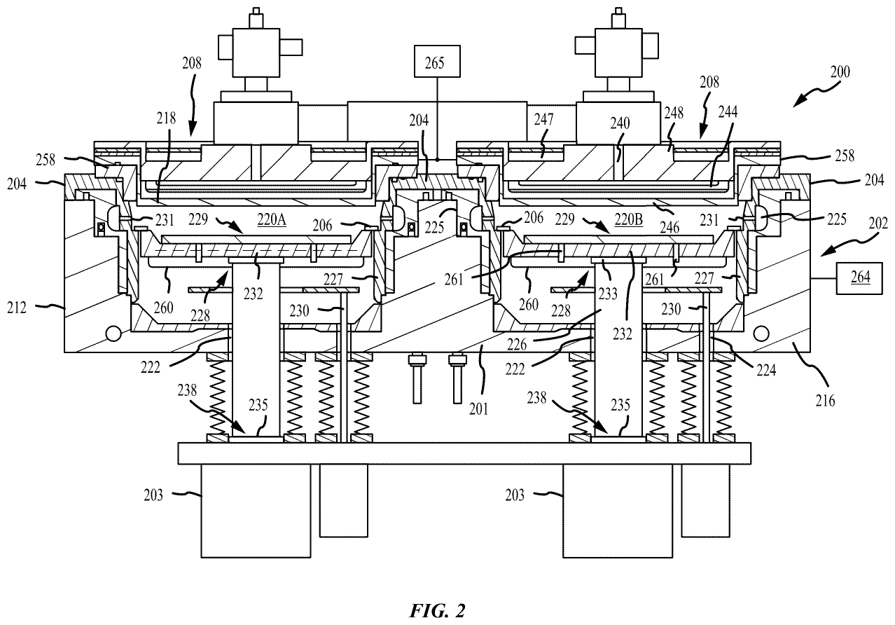

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include faceplates or other components or assemblies according to embodiments of the present technology. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a gas delivery assembly 218 into the processing region 220B. The gas delivery assembly 218 may include a gasbox 248 having a blocker plate 244 disposed intermediate to a faceplate 246. A radio frequency (“RF”) source 265 may be coupled with the gas delivery assembly 218, which may power the gas delivery assembly 218 to facilitate generating a plasma region between the faceplate 246 of the gas delivery assembly 218 and the pedestal 228, which may be the processing region of the chamber. In some embodiments, the RF source may be coupled with other portions of the chamber body 202, such as the pedestal 228, to facilitate plasma generation. A dielectric isolator 258 may be disposed between the lid 204 and the gas delivery assembly 218 to prevent conducting RF power to the lid 204. A shadow ring 206 may be disposed on the periphery of the pedestal 228 that engages the pedestal 228.

An optional cooling channel 247 may be formed in the gasbox 248 of the gas distribution system 208 to cool the gasbox 248 during operation. A heat transfer fluid, such as water, ethylene glycol, a gas, or the like, may be circulated through the cooling channel 247 such that the gasbox 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

FIG. 3 shows exemplary operations in a semiconductor processing method 300 according to some embodiments of the present technology. The method may be performed in a variety of processing chambers, including system 200 described above. Method 300 may include one or more operations prior to the initiation of the stated method operations, including front end processing, deposition, etching, polishing, cleaning, or any other operations that may be performed prior to the described operations. The method may include a number of optional operations as denoted in the figure, which may or may not specifically be associated with the method according to the present technology. For example, many of the operations are described in order to provide a broader scope of the semiconductor process, but are not critical to the technology, or may be performed by alternative methodology as will be discussed further below.

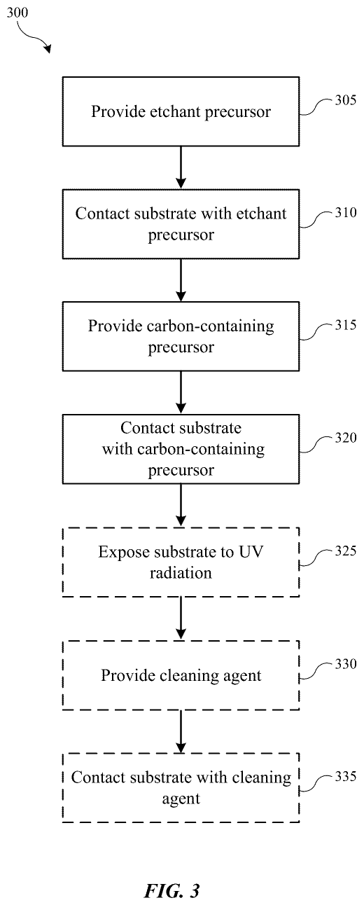

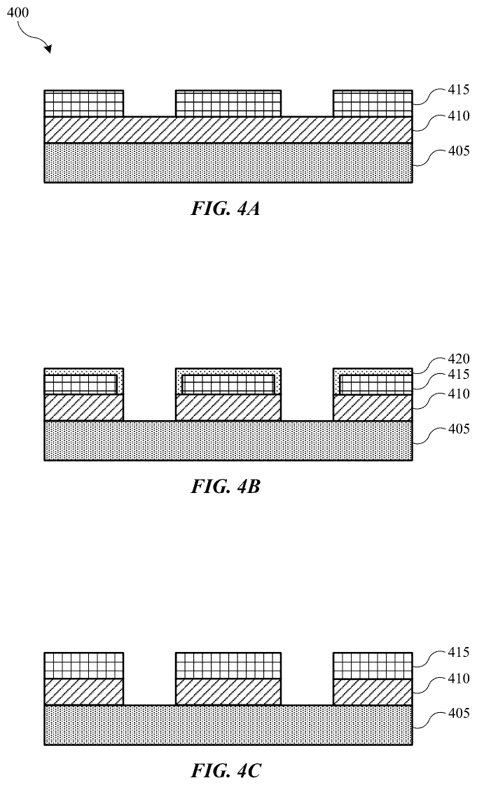

Method 300 may involve optional operations to develop the semiconductor structure to a particular fabrication operation. Although in some embodiments method 300 may be performed on a base structure, in some embodiments the method may be performed subsequent to other material formation or removal. For example, any number of deposition, masking, or removal operations may be performed to produce any transistor, memory, or other structural aspects on a substrate or structure. The substrate or structure may be disposed on a substrate support, which may be positioned within a processing region of a semiconductor processing chamber. The operations may be performed in the same chamber in which aspects of method 300 may be performed, and one or more operations may also be performed in one or more chambers on a similar platform as a chamber in which operations of method 300 may be performed, or on other platforms. Method 300 describes the operations shown schematically in FIGS. 4A-4C, the illustrations of which will be described in conjunction with the operations of method 300. It is to be understood that FIGS. 4A-4C illustrate only partial schematic views, and a substrate may contain any number of transistor sections having aspects as illustrated in the figures.

As shown in FIG. 4A, structure 400 may include a substrate 405. The substrate 405 may be made of or contain silicon or some other semiconductor substrate material. One or more layers of material may be formed over the substrate 405. The layers of material may include, for example, a first layer of material 410. The first layer of material 410 may be, for example, a first silicon-containing material or oxygen-containing material. In embodiments, while not illustrated, the first layer of material 410 may include both a first silicon-containing material or oxygen-containing material. The layers of material may also include a second silicon-containing material 415. The second silicon-containing material 415 may be, for example, silicon-and-oxygen-containing material, silicon-and-nitrogen-containing material, or silicon-oxygen-and-carbon-containing material. In embodiments, second silicon-containing material 415 may be characterized by a dielectric constant of less than or about 5.0.

At operation 305, method 300 may include providing one or more etchant precursors to the processing region of the semiconductor processing chamber. Method 300 may include contacting the substrate with the etchant precursor at operation 310, which may be used to remove carbon-containing material (e.g., carbon-containing spin-on material) from the substrate 405. The etchant precursors may include, for example, a hydrogen-containing precursor, a nitrogen-containing precursor, an oxygen-containing precursor, a helium-containing precursor, a halogen-containing precursor, or any other conventional semiconductor precursors used to remove silicon-containing material and/or oxygen-containing material. In one example, the one or more etchant precursors may include diatomic hydrogen (H₂) and diatomic nitrogen (N₂) The halogen-containing precursor may include, for example, a fluorine-containing precursor, a chlorine-containing precursor, or any other conventional semiconductor precursors used to remove oxygen-containing material, such as silicon-and-oxygen-containing material. In one example, the halogen-containing precursor may include dilute hydrofluoric acid (dHF) or any other wet halogen-containing etchant species. In another example, the halogen-containing precursor may include diatomic fluorine (F₂), nitrogen trifluoride (NF₃), nitrogen trichloride (NCl₃), boron trichloride (BCl₃), or any other dry halogen-containing etchant species. Other non-halogen-containing precursors, such as ammonia (NH₃) or inert gases, may also be provided with the etchant precursor. In embodiments, method 300 may include forming a plasma of the one or more etchant precursors to increase bombardment and removal of the silicon-containing material and/or the oxygen-containing material.

The plasma effluents of the etchant precursor may be generated at a plasma power of less than or about 5000 W, and may be generated at a plasma power of less than or about 4500 W, less than or about 4000 W, less than or about 3500 W, less than or about 3000 W, less than or about 2750 W, less than or about 2500 W, less than or about 2250 W, less than or about 2000 W, less than or about 1750 W, less than or about 1500 W, less than or about 1250 W, less than or about 1000 W, less than or about 750 W, less than or about 500 W, less than or about 250 W, or less. While a plasma of the etchant precursor may be generated in some embodiments, other embodiments may include a thermal process that does not include generating a plasma of the halogen-containing precursor.

As illustrated in FIG. 4B, the contacting at operation 310 may etch at least a portion of the first layer of material 410 from the substrate 405. The second silicon-containing material 415 may not be etched by the contacting at operation 410, but carbon depletion may occur at an upper and/or exposed portion of the second silicon-containing material 415, such as on exposed sidewalls of the second silicon-containing material 415. Thus, while etching the first layer of material 410 from the substrate 405 at operation 310, carbon may be depleted from a portion of the second silicon-containing material 415, resulting in a carbon-depleted portion of the second silicon-containing material 420. Prior to operation 310, an exposed surface of the second silicon-containing material 415 may be characterized by a carbon concentration, which may be measured using X-ray photoelectron spectroscopy (XPS), of greater than or about 5 at. %, such as greater than or about 6 at. %, greater than or about 7 at. %, greater than or about 8 at. %, greater than or about 9 at. %, greater than or about 10 at. %, greater than or about 11 at. %, greater than or about 12 at. %, greater than or about 13 at. %, greater than or about 14 at. %, greater than or about 15 at. %, greater than or about 16 at. %, greater than or about 17 at. %, greater than or about 18 at. %, greater than or about 19 at. %, greater than or about 20 at. %, greater than or about 21 at. %, greater than or about 22 at. %, greater than or about 23 at. %, greater than or about 24 at. %, greater than or about 25 at. %, or more. During operation 310, carbon may be removed at a quicker rate relative to other elements in the second silicon-containing material 415, such as silicon, oxygen, and other elements. Carbon may outgas during the etching of the first layer of material 410. After operation 310, the second silicon-containing material 415 may be characterized by a carbon concentration, which may be measured using XPS, of less than or about 15 at. %, such as less than or about 14 at. %, less than or about 13 at. %, less than or about 12 at. %, less than or about 11 at. %, less than or about 10 at. %, or less. In embodiments, operation 310 may reduce the carbon concentration in the second silicon-containing material 415, such as at the surface, by greater than or about 0.1 at. %, greater than or about 0.5 at. %, greater than or about 1 at. %, greater than or about 1.5 at. %, greater than or about 2 at. %, greater than or about 2.5 at. %, greater than or about 3 at. %, greater than or about 4 at. %, greater than or about 5 at. %, greater than or about 7 at. %, greater than or about 8 at. %, greater than or about 9 at. %, greater than or about 10 at. %, or more. If left untreated, the carbon-depleted portion of the second silicon-containing material 420 would be susceptible to damage and/or removal during subsequent operations, such as subsequent etching operations, such as thermal, dry pre-cleans. As such, method 300 and the present technology may perform a carbon treatment to replenish carbon in the carbon-depleted portion of the second silicon-containing material 420. The carbon treatment may rehabilitate the carbon-depleted portion of the second silicon-containing material 420 to increase resistance to subsequent etching operations, such as thermal, dry pre-cleans.

To perform the carbon treatment, method 300 may include providing a carbon-containing precursor to the processing region of the semiconductor processing chamber at operation 315. The carbon-containing precursor may be any precursor including carbon and may also include silicon and/or oxygen. In embodiments, the carbon-containing precursor may be or include hexamethyldisilazane (HMDS), tetramethyldisilazane (TMDS), trimethylchlorosilane (TMCS), dimethyldichlorosilane (DMDCS), methyltrichlorosilane (MTCS), trimethylmethoxysilane (TMMS) (CH₃—O—Si—(CH₃)₃), dimethyldimethoxysilane (DMDMS) ((CH₃)₂—Si—(OCH₃)₂), methyltrimethoxysilane (MTMS) ((CH₃—O)₃—Si—CH₃), phenyltrimethoxysilane (PTMOS) (C₆H₅—Si—(OCH₃)₃), phenyldimethylchlorosilane (PDMCS) (C₆H₅—Si(Cl)—(CH₃)₂), dimethylaminotrimethylsilane (DMATMS) ((CH₃)₂—N—Si—(CH₃)₃), or bis(dimethylamino)dimethylsilane (BDMADMS), as well as any other carbon-containing precursor that may be used in semiconductor processing. The precursors may or may not include delivery of additional precursors, such as one or more carrier gases to assist the flow of the carbon-containing precursor. The carrier gases may include helium, argon, or diatomic nitrogen.

In embodiments, method 300 may include generating a plasma of the carbon-containing precursor. The plasma effluents of the carbon-containing precursor may be generated at a plasma power of less than or about 3000 W, and may be generated at a plasma power of less than or about 2750 W, less than or about 2500 W, less than or about 2250 W, less than or about 2000 W, less than or about 1750 W, less than or about 1500 W, less than or about 1250 W, less than or about 1000 W, less than or about 750 W, less than or about 500 W, less than or about 250 W, or less. While a plasma of the carbon-containing precursor may be generated in some embodiments, other embodiments may include a thermal process that does not include generating a plasma of the carbon-containing precursor.

At operation 320, method 300 may include contacting the substrate with the carbon-containing precursor. The contacting with the carbon-containing precursor may replenish carbon in the carbon-depleted portion of the second silicon-containing material 420. As illustrated in FIG. 4C, the contacting may return the carbon-depleted portion of the second silicon-containing material 420 to being similar or the same as the second silicon-containing material 415. However, it is contemplated that the contacting at operation 320 may not fully restore carbon in the carbon-depleted portion of the second silicon-containing material 420. In embodiments, contacting the second silicon-containing material 415 with the carbon-containing precursor at operation 320 may increase the carbon concentration, which may be measured using XPS, at the exposed surface of the second silicon-containing material 415 by greater than or about 0.1 at. %, such as greater than or about 0.5 at. %, greater than or about 1 at. %, greater than or about 1.5 at. %, greater than or about 2 at. %, greater than or about 2.5 at. %, greater than or about 3 at. %, greater than or about 4 at. %, greater than or about 5 at. %, greater than or about 7 at. %, greater than or about 8 at. %, greater than or about 9 at. %, greater than or about 10 at. %, or more. In embodiments, the increase in carbon concentration may be directed to the surface of the second silicon-containing material 415, although it is contemplated the increase may also penetrate a portion of the second silicon-containing material 415.

At optional operation 325, method 300 may include exposing the substrate 405 to ultraviolet (UV) radiation. The UV radiation source may be, for example, a UV lamp. The UV radiation source may be positioned outside of the semiconductor processing chamber, and the semiconductor processing chamber may have a quartz window through which UV radiation may pass. The structure 400 may be positioned in an inert gas environment, such as, for example, helium, argon, or diatomic nitrogen. The processing semiconductor chamber may include a microwave source to heat the second silicon-containing material 415 prior to or concurrently with contacting the silicon-containing material with UV radiation. In embodiments, the UV radiation exposure may be conducted using a plasma to simulate UV radiation wavelengths. The plasma may be formed by coupling RF power to a treatment gas such as, for example, helium, argon, molecular oxygen, or diatomic oxygen. Exposing the second silicon-containing material 415 to UV radiation may break Si—H and/or SI—OH bonds in the material, allowing Si—CH₂—CH₂—Si(CH₃)₃ and/or Si—O—Si(CH₃)₃ bonds to form, thereby increasing the carbon concentration.

During operation 325, conditions of the UV radiation may be tailored to treat the second silicon-containing material 415. For example, a UV irradiance power may be characterized by between about 100 W/m² and about 2000 W/m². At UV irradiance powers less than 100 W/m², the UV radiation may not be significant enough to modify the material. At UV irradiance powers greater than 2000 W/m², the UV radiation may damage the material or structure. Additionally, a UV wavelength may be characterized by between about 100 nm and about 400 nm. A UV wavelength below 100 nm may require a special light source that may not be commonly available. A UV wavelength above 400 nm, such as visible light, may not have sufficient energy to modify the previously discussed bonds.

In embodiments, contacting the second silicon-containing material 415 with the carbon-containing precursor and exposing the substrate to ultraviolet (UV) radiation may be performed simultaneously. Specifically, operations 320 and 325 may be performed simultaneously to treat the second silicon-containing material 415. However, it is still contemplated that the operations may be performed in sequence in some embodiments.

At optional operation 330, subsequent to the contacting at operation 320 and/or the exposure to UV radiation at optional operation 325, method 300 may include providing a cleaning agent to the processing region of the semiconductor processing chamber. The cleaning agent may be any wet etchant and may be, for example, a fluorine-containing cleaning agent. In embodiments, the fluorine-containing cleaning agent may be or include dilute hydrofluoric acid. The cleaning agent may also be a cleaning plasma, such as a halogen-containing plasma, a hydrogen-containing plasma, a nitrogen-containing plasma, a helium-containing plasma, or an oxygen-containing plasma. At optional operation 335, method 300 may include contacting the substrate 405 with the cleaning agent. The contacting with the cleaning agent may remove a residue from the substrate 405, such as a native oxide or other residue from the previous operations of method 300.

The operations of method 300 may be repeated for a second cycle, and may be repeated of any number of cycles. The operations 505-540 of the second cycle or any subsequent cycle of method 300 may be similar to and may include any features or characteristics as operation 305-330 as previously discussed with regard to the first cycle of method 300.

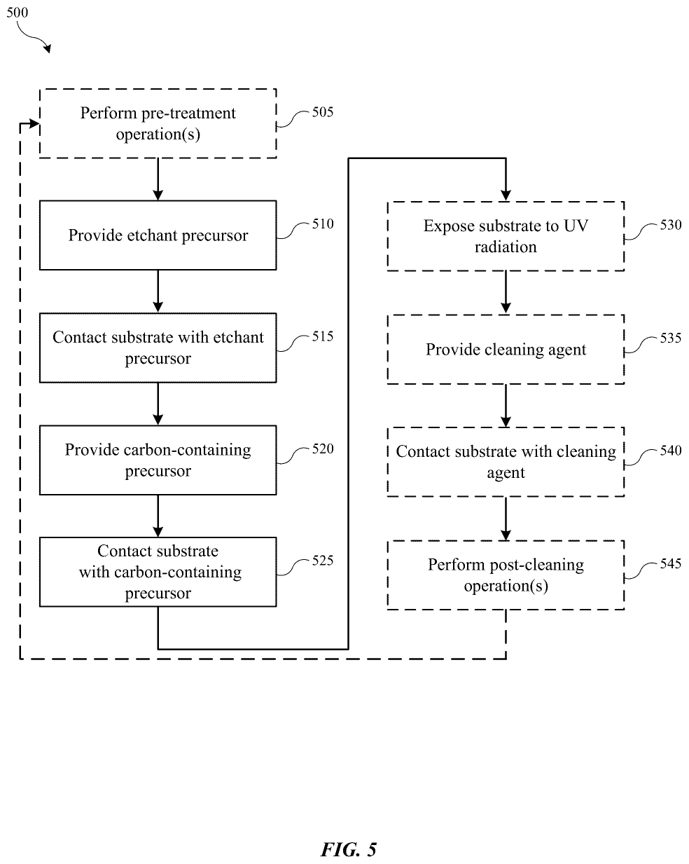

FIG. 5 shows exemplary operations in a semiconductor processing method 500 according to some embodiments of the present technology. The method may be performed in a variety of processing chambers, including system 200 described above. Method 500 may include one or more operations prior to the initiation of the stated method operations, including front end processing, deposition, etching, polishing, cleaning, or any other operations that may be performed prior to the described operations. The method may include a number of optional operations as denoted in the figure, which may or may not specifically be associated with the method according to the present technology. For example, many of the operations are described in order to provide a broader scope of the semiconductor process, but are not critical to the technology, or may be performed by alternative methodology as will be discussed further below.

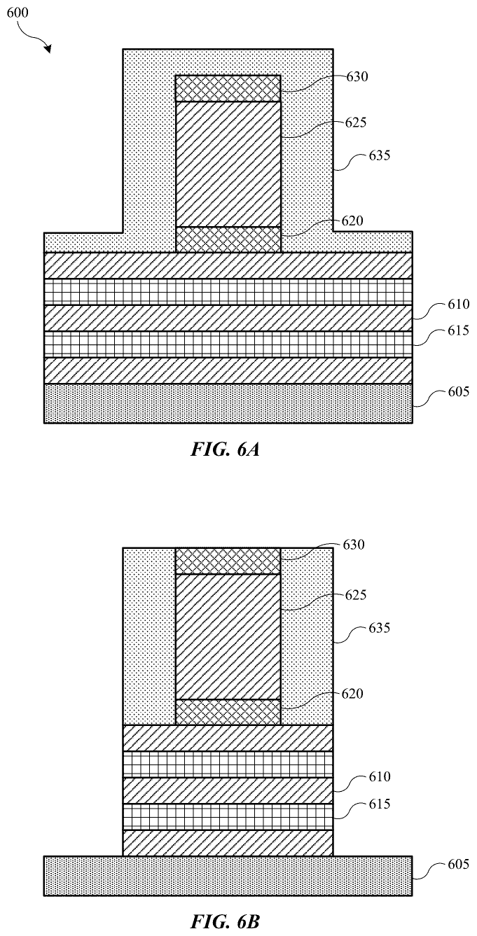

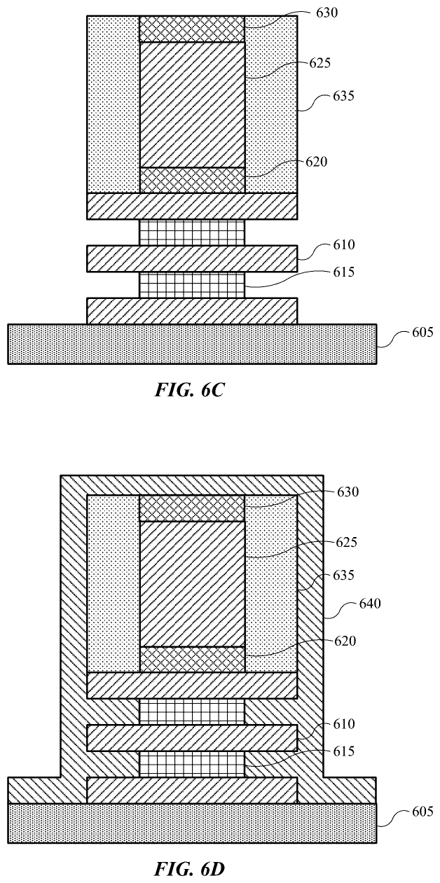

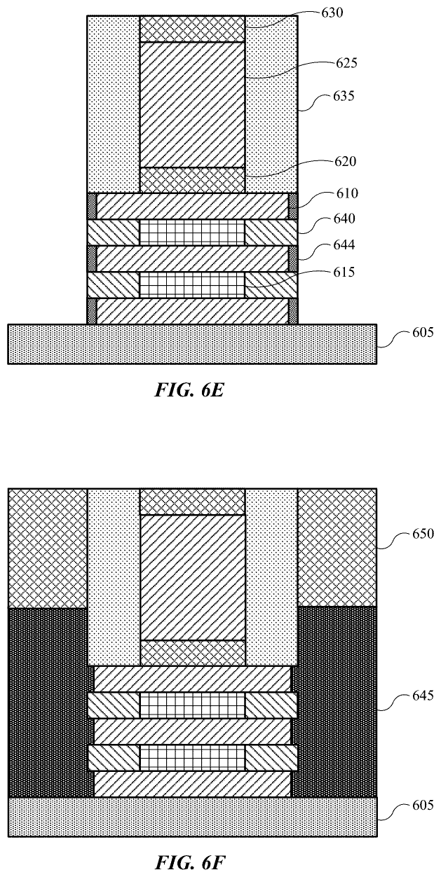

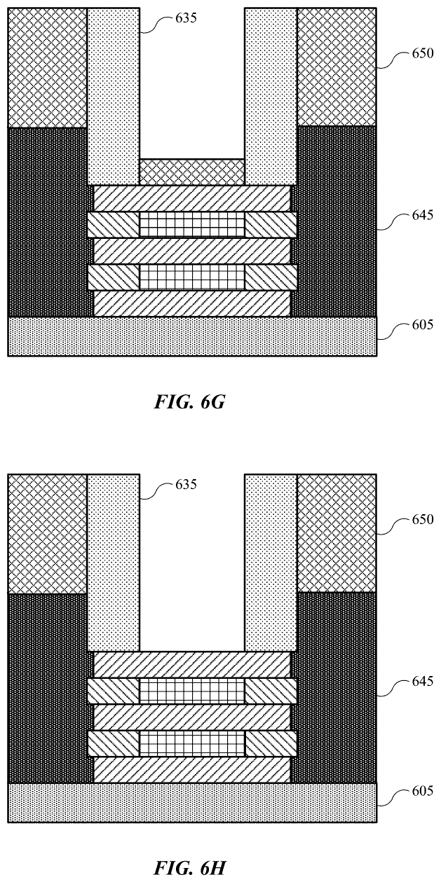

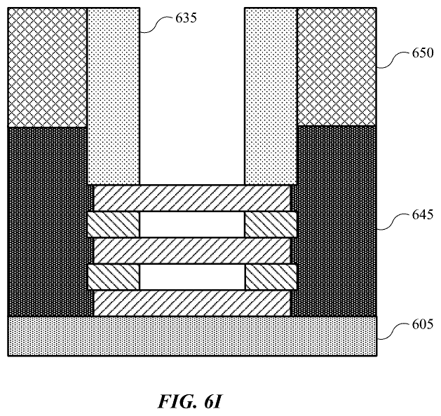

Method 500 may involve optional operations to develop the semiconductor structure to a particular fabrication operation. Although in some embodiments method 500 may be performed on a base structure, in some embodiments the method may be performed subsequent to other material formation or removal. For example, any number of deposition, masking, or removal operations may be performed to produce any transistor, memory, or other structural aspects on a substrate. The substrate may be disposed on a substrate support, which may be positioned within a processing region of a semiconductor processing chamber. The operations may be performed in the same chamber in which aspects of method 500 may be performed, and one or more operations may also be performed in one or more chambers on a similar platform as a chamber in which operations of method 500 may be performed, or on other platforms. Method 500 describes the operations shown schematically in FIGS. 6A-6I, the illustrations of which will be described in conjunction with the operations of method 500. It is to be understood that FIGS. 6A-6I illustrate only partial schematic views, and a substrate may contain any number of transistor sections having aspects as illustrated in the figures.

As shown in FIG. 6A, structure 600 may include a substrate 605. The substrate 605 may be made of or contain silicon or some other semiconductor substrate material. One or more layers of material may be formed over the substrate 605. For example, alternating layers of material may be deposited on the substrate 605. The alternating layers of material may include, for example, layers of a silicon-containing material 610, such as silicon, and layers of a silicon-and-germanium-containing material 615, such as silicon germanium. A dummy gate 625, which may be replaced with a metal in subsequent operations, may be deposited over the alternating layers of the silicon-containing material 610 and layers of the silicon-and-germanium-containing material 615. The dummy gate 625 may be any suitable material, such as a silicon-containing material (e.g., silicon or polysilicon) an oxygen-containing material, or a metal-containing material (e.g., titanium-containing material), and may be separated from the alternating layers of material by a layer of a silicon-containing material 620, such as silicon oxide or silicon nitride. Similarly, a layer of a silicon-containing material 630, such as silicon oxide or silicon nitride, may be formed over the dummy gate 625.

A gate spacer 635 may be formed on the substrate 605 overlying the materials previously described. The gate spacer 635 may be a silicon-containing material, such as low dielectric constant material that may include silicon, oxygen, carbon, nitrogen, or combinations thereof. For example, the gate spacer 635 may be a silicon-and-oxygen-containing material or a silicon-oxygen-and-carbon-containing material. These silicon-containing conformal materials, such as silicon-and-oxygen-containing material or silicon-oxygen-and-carbon-containing material, exhibit lower dielectric constants than other conformal materials, which makes these silicon-containing materials useful in GAA applications. The silicon-containing material of the gate spacer 635 may be characterized by a dielectric constant of less than or about 7.5, such as less than or about 7.0, less than or about 6.5, less than or about 6.0, less than or about 5.5, less than or about 5.0, or less. Additionally, the silicon-containing material of the gate spacer 635 may have a conformality of greater than or about 90%. However, as discussed below, subsequent GAA processing may utilize wet etchants, and these silicon-containing materials may have poor resistance to these wet etchants or cleaning agents. The poor resistance has challenged the use of these low dielectric constant conformal materials. During method 500, individual materials may be removed relative to other material in the structure 600. However, these removal operations may deplete one or more constituents, such as carbon, in materials to be maintained. A replenishment treatment may be performed to increase the concentration of one or more constituents, such as carbon, in the materials to be maintained. The replenishment treatment may prevent thickness loss during subsequent operations.

At optional operation 505, method 500 may include pre-treatment operations to prepare the substrate 605 for further processing. For example, optional operation 505 may include operations to develop the GAA structure illustrated in FIG. 6A. These operations may include, but are not limited to, depositing blanket films of the silicon-containing material 610 and the silicon-and-germanium-containing material 615. The operations may also include the formation of the layer of the silicon-containing material 620, the dummy gate 625, and layer of the silicon-containing material 630. After the formation of silicon-containing material 630, the gate spacer 635 may be formed over all the layers.

At operation 510, method 500 may include providing one or more etchant precursors to the processing region of the semiconductor processing chamber. The etchant precursors may include, for example, a hydrogen-containing precursor, a nitrogen-containing precursor, an oxygen-containing precursor, a helium-containing precursor, a halogen-containing precursor, or any other conventional semiconductor precursors used to remove silicon-containing material. In one example, the one or more etchant precursors may include a fluorine-containing precursor, a chlorine-containing precursor, an oxygen-containing precursor and/or an inert gas. The inert gas may be or include argon, helium, neon, xenon, or any noble and inert material used or useful in semiconductor processing. In embodiments, method 500 may include forming a plasma of the one or more etchant precursors to increase bombardment and removal of material, such as the gate spacer 635, the silicon-containing material 610, and the silicon-and-germanium-containing material 615.

At operation 515, method 500 may include contacting the substrate 605 with the one or more etchant precursors. Method 500 may include etching a portion of the silicon-containing material, referred to as the gate spacer 635, from the substrate 605, as well as etching cavities through the silicon-containing material 610 and the silicon-and-germanium-containing material 615. As illustrated in FIG. 6B, the one or more etchant precursors may contact the substrate 605 and remove a portion of the gate spacer 635, the silicon-containing material 610, and the silicon-and-germanium-containing material 615. The etching may leave a portion of the silicon-containing material of gate spacer 635, such as the portion extending above the uppermost silicon-containing material 610 or silicon-and-germanium-containing material 615 of the alternating layers of material. In embodiments, operation 515 may be a source and drain cavity reactive ion etching (RIE) in GAA processing.

After the etching at operation 515, carbon may be depleted from an exposed portion of the silicon-containing material of the gate spacer 635. Accordingly, performing a carbon replenishment operation subsequent to operation 515 may prevent thickness loss of the gate spacer 635 during subsequent operations. In embodiments, a pre-clean may be performed prior to the carbon replenishment operation to remove one or more residues from the gate spacer 635 that may limit effectiveness of the carbon replenishment operation. At operation 520, method 500 may include providing a carbon-containing precursor to the processing region of the semiconductor processing chamber. Operation 520 may be similar to and may include any features or characteristics as operation 315 previously discussed. At operation 525, method 500 may include contacting the substrate with the carbon-containing precursor. The contacting at operation 525 may replenish carbon in the gate spacer 635. Operation 525 may be similar to and may include any features or characteristics as operation 320 previously discussed. In embodiments, a pre-clean may be performed prior to operation 515 to remove one or more residues from the gate spacer 635 that may limit effectiveness of the carbon replenishment operation.

Similar to method 300, method 500 may include exposing the substrate 605 to UV radiation at optional operation 530. Optional operation 530 may be similar to and may include any features or characteristics as operation 325 previously discussed.

At optional operation 535, method 500 may include providing a cleaning agent to the processing region of the semiconductor processing chamber. The cleaning agent may be any wet etchant and may be, for example, a fluorine-containing cleaning agent. In embodiments, the fluorine-containing cleaning agent may be or include dilute hydrofluoric acid (dHF). The cleaning agent may also be a dry etchant, such as a fluorine-containing precursor that may be plasma-enhanced or not. At optional operation 540, method 500 may include contacting the substrate 605 with the cleaning agent. The cleaning agent may be provided to clean the structure 600 after the contacting at operation 525, which may leave a residue, such as an oxygen-containing material on one or more materials present on the substrate. Without performing the carbon replenishment, the carbon depleted material, such as the gate spacer 635, may be etched at optional operation 535. However, the gate spacer 635 after the carbon replenishment may be more resistant to the cleaning at optional operations 535-540 and may not suffer from thickness loss during the cleaning.

Method 500 may include performing post-cleaning operation(s) at optional operation 545. For example, as illustrated in FIG. 6C, the layers of the silicon-and-germanium-containing material 615 may be recessed relative to the layers of the silicon-containing material 610. Additionally, as illustrated in FIG. 6D, an inner spacer 640 may be deposited. The inner spacer 640 may be similar to and may include any features or characteristics as the gate spacer 635 previously discussed.

After performing post-cleaning operation(s) at optional operation 545, the operations of method 500 may be repeated for a second iteration. The operations 505-540 of the second iteration of method 500 may be similar to and may include any features or characteristics as operation 505-540 as previously discussed with regard to the first iteration of method 500. First, any pre-treatment operations may be performed at optional operation 505 of the second iteration of method 500. At operation 510 of the second iteration of method 500, one or more etchant precursors may be provided to the processing region of the semiconductor processing chamber. For example, the one or more etchant precursors may include a fluorine-containing precursor, a chlorine-containing precursor, an oxygen-containing precursor and/or an inert gas. In embodiments, the second iteration of method 500 may include forming a plasma of the one or more etchant precursors to increase bombardment and removal of material, such as the inner spacer 640.

At operation 515 of the second iteration of method 500, the substrate 605 may be contacted with the one or more etchant precursors. Method 500 may include etching a portion of the silicon-containing material, referred to as the inner spacer 640, from the substrate 605. As illustrated in FIG. 6E, the one or more etchant precursors may contact the substrate 605 and remove a portion of the inner spacer 640. The etching may leave a portion of the inner spacer 640, such as the portion extending into recesses defined by the silicon-containing material 610 and silicon-and-germanium-containing material 615 of the alternating layers of material. In embodiments, operation 515 of the second iteration of method 500 may be an inner spacer RIE in GAA processing.

The etching at operation 515 of the second iteration of method 500 may deplete carbon from an exposed portion of the inner spacer 640 and/or gate spacer 635. Conversely, an oxygen concentration in the silicon-containing material of the inner spacer 640 may increase during the contacting at operation 525 of the second iteration of method 500, which may be due to the interaction between the one or more etchant precursors, such as an oxygen-containing precursor, and/or etch byproducts and the silicon-containing material of the inner spacer 640. In order to maintain the spacer 435 during subsequent operations, such as in GAA processing, it may be desirable or necessary to replenish the carbon in the inner spacer 640. Therefore, a carbon replenishment treatment may be performed as further discussed below. However, the presence of any oxygen-containing material may also undesirably react with a carbon-containing precursor during the carbon replenishment treatment.

Similar to the oxygen concentration in the silicon-containing material of the inner spacer 640 increasing during operation 525 of the second iteration of method 500, a portion of layer of the silicon-containing material 610 may also oxidize when an oxygen-containing precursor or oxygen-containing byproduct is present. The oxidation of the silicon-containing material 610 may form an oxygen-containing material 644 on the silicon-containing material 610. Additionally or alternatively, after etching a portion of the silicon-containing material, referred to as the inner spacer 640, from the substrate 605, the substrate 605 may be transferred to another processing region of another semiconductor processing chamber. However, it is also contemplated that the substrate 605 may remain in the same processing region of the same semiconductor processing chamber. Regardless, as shown in FIG. 6E, oxygen-containing material 644, which may be referred to as a native oxide or surface oxide, may be present on the silicon-containing material 610 after etching a portion of the inner spacer 640. The oxygen-containing material 644 may be an oxidized portion of the silicon-containing material 610 that may form due to interaction with the etchant precursors and/or etch byproducts. Additionally or alternatively, the oxygen-containing material 644 may be an oxidized portion of the silicon-containing material 610 that may form due to exposure to ambient conditions. If left untreated, carbon in the carbon replenishment treatment as further discussed below may bond with oxygen in the oxygen-containing material 644 which may increase the variability of the surface for subsequent GAA processing, such as during epitaxial growth operations. Accordingly, method 500 may include providing a halogen-containing precursor to the processing region of the semiconductor processing chamber for the purpose of removing the oxygen-containing material 644.

The halogen-containing precursor may include, for example, a fluorine-containing precursor, a chlorine-containing precursor, or any other conventional semiconductor precursors used to remove oxygen-containing material, such as silicon-and-oxygen-containing material. In one example, the halogen-containing precursor may include dilute hydrofluoric acid (dHF) or any other wet halogen-containing etchant species. In another example, the halogen-containing precursor may include diatomic fluorine (F₂), nitrogen trifluoride (NF₃), nitrogen trichloride (NCl₃), boron trichloride (BCl₃), or any other dry halogen-containing etchant species. Other non-halogen-containing precursors, such as ammonia (NH₃) or inert gases, may also be provided with the halogen-containing precursor. In embodiments, a plasma of the halogen-containing precursor may be formed to increase bombardment and removal of the oxygen-containing material 644.

The plasma effluents of the halogen-containing precursor may be generated at a plasma power of less than or about 5000 W, and may be generated at a plasma power of less than or about 4500 W, less than or about 4000 W, less than or about 3500 W, less than or about 3000 W, less than or about 2750 W, less than or about 2500 W, less than or about 2250 W, less than or about 2000 W, less than or about 1750 W, less than or about 1500 W, less than or about 1250 W, less than or about 1000 W, less than or about 750 W, less than or about 500 W, less than or about 250 W, or less. While a plasma of the halogen-containing precursor may be generated in some embodiments, other embodiments may include a thermal process that does not include generating a plasma of the halogen-containing precursor.

The method may include contacting the substrate 605 with the halogen-containing precursor. Contacting the substrate 605 and the oxygen-containing material 644 with the halogen-containing precursor may introduce halogenic material to the oxygen-containing material 644 of the silicon-containing material 610. The introduction of halogenic material and contacting may etch a portion of the layer of the silicon-containing material 610, such as the oxygen-containing material 644, from the substrate 605. The halogen-containing material may be provided in liquid phase or vapor phase, which may allow the halogen-containing precursor to thoroughly contact the oxygen-containing material 644 of the silicon-containing material 610.

Contacting the oxygen-containing material 644 of the silicon-containing material 610 with the halogen-containing precursor or the plasma effluents thereof may decrease variability of the structure 600 after the subsequent carbon replenishment treatment may be performed as further discussed below. As previously discussed, without removing the oxygen-containing material 644 that may be present, carbon in the carbon replenishment treatment may bond with oxygen in the oxygen-containing material 440. The formation of C—O bonds may increase the variability of the surface for subsequent GAA processing, such as during epitaxial growth operations. Instead, the contacting may remove hydroxyl (—OH) bonds from the surface of the layer of the silicon-containing material 644. Therefore, the contacting may remove surface terminations that may be prone to bonding with carbon during the carbon replenishment treatment.

The contacting may remove the oxygen-containing material 644 and/or a portion of the silicon-containing material 610. In embodiments, to ensure the oxygen-containing material 644 is removed, a thickness of the oxygen-containing material and/or the portion of the layer of the silicon-containing material 641 that is removed may be greater than or about 10 Å, and may be greater than or about 15 Å, greater than or about 20 Å, greater than or about 25 Å, greater than or about 30 Å, greater than or about 35 Å, greater than or about 40 Å, greater than or about 45 Å, greater than or about 50 Å, greater than or about 55 Å, greater than or about 60 Å, or more.

As previously discussed, the etching at operation 515 of the second iteration of method 500 may deplete carbon from an exposed portion of the inner spacer 640 and/or gate spacer 635. Accordingly, performing a second carbon replenishment operation subsequent to operation 515 of the second iteration of method 500 may prevent thickness loss of the inner spacer 640 and/or gate spacer 635 during subsequent operations. At operation 520 of the second iteration of method 500, method 500 may include providing a carbon-containing precursor to the processing region of the semiconductor processing chamber. Operation 520 of the second iteration of method 500 may be similar to and may include any features or characteristics as operation 520 of the first iteration of method 500 and/or operation 315 previously discussed. At operation 525 of the second iteration of method 500, method 500 may include contacting the substrate with the carbon-containing precursor. The contacting at operation 525 may replenish carbon in the inner spacer 640 and/or gate spacer 635. Operation 525 of the second iteration of method 500 may be similar to and may include any features or characteristics as operation 525 of the first iteration of method 500 and/or operation 320 previously discussed. In embodiments, a pre-clean may be performed prior to operation 520 of the second iteration of method 500 to remove one or more residues from the inner spacer 640 and/or gate spacer 635 that may limit effectiveness of the carbon replenishment operation.

Similar to the first iteration of method 500 and to method 300, the second iteration of method 500 may include exposing the substrate 605 to UV radiation at optional operation 530. Optional operation 530 of the second iteration of method 500 may be similar to and may include any features or characteristics as operation 525 of the first iteration of method 500 and/or operation 325 previously discussed.

At optional operation 535, the second iteration of method 500 may include providing a cleaning agent to the processing region of the semiconductor processing chamber. The cleaning agent may be any wet etchant and may be, for example, a fluorine-containing cleaning agent. In embodiments, the fluorine-containing cleaning agent may be or include dHF. The cleaning agent may also be a dry etchant, such as a fluorine-containing precursor that may be plasma-enhanced or not. Operation 535 of the second iteration of method 500 may be similar to and may include any features or characteristics as operation 535 of the first iteration of method 500. At optional operation 540, the second iteration of method 500 may include contacting the substrate 605 with the cleaning agent. The cleaning agent may be provided to clean the structure 600 after the contacting at operation 525, which may leave a residue, such as an oxygen-containing material on one or more materials present on the substrate. Operation 540 of the second iteration of method 500 may be similar to and may include any features or characteristics as operation 540 of the first iteration of method 500. Without performing the carbon replenishment, the carbon depleted material, such as the inner spacer 640 and/or gate spacer 635, may be etched at optional operation 535. However, the inner spacer 640 and/or gate spacer 635 after the carbon replenishment may be more resistant to the cleaning at optional operations 535-540 and may not suffer from thickness loss during the cleaning.

Method 500 may include performing post-cleaning operation(s) at optional operation 545. For example, as illustrated in FIG. 6F, epitaxial material 645 may be deposited on the substrate 605 at optional operation 545 of the second iteration of method 500. Additionally, interlayer dielectric material 650 may be formed over the epitaxial material 645 at optional operation 545 of the second iteration of method 500. The interlayer dielectric material 650 may serve to separate individual gates of a GAA structure.

Deposition of the epitaxial material 645 may include additional carbon replenishment operations. For example, in conventional deposition of epitaxial material, one skilled in the art would recognize the process flow of depositing a P-epi hardmask material, patterning the hardmask material (with the possible use of an additional mask material and subsequent removal of the additional mask), epitaxial growth, and hardmask material stripping or removal. Similarly, one skilled in the art would recognize the similar process flow for N-epi deposition. For example, one skilled in the art would recognize the process flow of depositing a N-epi hardmask material, patterning the hardmask material (with the possible use of an additional mask material and subsequent removal of the additional mask), epitaxial growth, and hardmask material stripping or removal.

While not illustrated in the figures, one skilled in the art would appreciate the possibility of carbon replenishment subsequent to patterning the hardmask material for both P-epi formation and N-epi formation, as well as stripping any remaining hardmask material after formation of the epitaxial material 645. As such, the present technology may include one or more carbon replenishment operations, such as operations 520-530 of method 500 or method 300, prior to any subsequent cleaning or etching operations. The carbon replenishment operations may reintroduce carbon to any exposed materials containing carbon, such as inner spacer 640, that may be carbon depleted while patterning the hardmask material for both P-epi formation and N-epi formation, as well as stripping any remaining hardmask material after formation of the epitaxial material 645.

After performing post-cleaning operation(s) at optional operation 545, the operations of method 500 may be repeated for a third iteration. The operations 505-540 of the third iteration of method 500 may be similar to and may include any features or characteristics as operation 505-540 as previously discussed with regard to the first iteration and/or second iteration of method 500. First, any pre-treatment operations may be performed at optional operation 505 of the third iteration of method 500. At operation 510 of the third iteration of method 500, one or more etchant precursors may be provided to the processing region of the semiconductor processing chamber. For example, the one or more etchant precursors may include a fluorine-containing precursor, a chlorine-containing precursor, an oxygen-containing precursor and/or an inert gas. In embodiments, the third iteration of method 500 may include forming a plasma of the one or more etchant precursors to increase bombardment and removal of material, such as the silicon-containing material 630 and/or the dummy gate 625.

At operation 515 of the third iteration of method 500, the substrate 605 may be contacted with the one or more etchant precursors. The third iteration of method 500 may include etching a portion of the silicon-containing material 630 and the dummy gate 625 from the substrate 605. As illustrated in FIG. 6G, the one or more etchant precursors may contact the substrate 605 and remove a portion of the silicon-containing material 630 and the dummy gate 625. The etching may remove the silicon-containing material 630 and the dummy gate 625 entirely. Alternatively, some residue of the silicon-containing material 630 and/or the dummy gate 625 may remain on the gate spacer 635 and/or the silicon-containing material 620. In embodiments, operation 515 of the third iteration of method 500 may be a polysilicon pull in GAA processing.

The etching at operation 515 of the third iteration of method 500 may deplete carbon from an exposed portion of the gate spacer 635. Accordingly, performing a third carbon replenishment operation subsequent to operation 515 of the third iteration of method 500 may prevent thickness loss of the gate spacer 635 during subsequent operations. At operation 520 of the third iteration of method 500, method 500 may include providing a carbon-containing precursor to the processing region of the semiconductor processing chamber. Operation 520 of the third iteration of method 500 may be similar to and may include any features or characteristics as operation 520 of the first iteration of method 500, operation 520 of the second iteration of method 500, and/or operation 315 previously discussed. At operation 525 of the third iteration of method 500, method 500 may include contacting the substrate 605 with the carbon-containing precursor. The contacting at operation 525 may replenish carbon in the gate spacer 635. Operation 525 of the third iteration of method 500 may be similar to and may include any features or characteristics as operation 525 of the first iteration of method 500, operation 525 of the second iteration of method 500, and/or operation 320 previously discussed. In embodiments, a pre-clean may be performed prior to operation 520 of the third iteration of method 500 to remove one or more residues from the gate spacer 635 that may limit effectiveness of the carbon replenishment operation.

Similar to the first iteration and second iteration of method 500 and to method 300, the third iteration of method 500 may include exposing the substrate 605 to UV radiation at optional operation 530. Optional operation 530 of the third iteration of method 500 may be similar to and may include any features or characteristics as operation 525 of the first iteration of method 500, the second iteration of method 500, and/or operation 325 previously discussed.

At optional operation 535, the third iteration of method 500 may include providing a cleaning agent to the processing region of the semiconductor processing chamber. The cleaning agent may be any wet etchant and may be, for example, a fluorine-containing cleaning agent. In embodiments, the fluorine-containing cleaning agent may be or include dHF. The cleaning agent may also be a dry etchant, such as a fluorine-containing precursor that may be plasma-enhanced or not. Operation 535 of the third iteration of method 500 may be similar to and may include any features or characteristics as operation 535 of the first iteration of method 500 and/or operation 535 of the second iteration of method 500. At optional operation 540, the third iteration of method 500 may include contacting the substrate 605 with the cleaning agent. The cleaning agent may be provided to clean the structure 600 after the contacting at operation 525, which may leave a residue, such as an oxygen-containing material on one or more materials present on the substrate 605. Operation 540 of the third iteration of method 500 may be similar to and may include any features or characteristics as operation 540 of the first iteration of method 500 and/or operation 540 of the second iteration of method 500. Without performing the carbon replenishment, the carbon depleted material, such as the gate spacer 635, may be etched at optional operation 535. However, the gate spacer 635 after the carbon replenishment may be more resistant to the cleaning at optional operations 535-540 and may not suffer from thickness loss during the cleaning.

The third iteration of method 500 may include performing post-cleaning operation(s) at optional operation 545.

At operation 515 of a fourth iteration of method 500, the substrate 605 may be contacted with the one or more etchant precursors. The fourth iteration of method 500 may include etching the silicon-containing material 620 from the substrate 605. As illustrated in FIG. 6H, the one or more etchant precursors may contact the substrate 605 and remove a portion of the silicon-containing material 620. The etching may remove the silicon-containing material 620 entirely. Alternatively, some residue of the silicon-containing material 620 may remain on the gate spacer 635. In embodiments, operation 515 of the fourth iteration of method 500 may be a dummy oxide removal in GAA processing.

The etching at operation 515 of the fourth iteration of method 500 may deplete carbon from an exposed portion of the gate spacer 635 and/or inner spacer 640. Accordingly, performing a third carbon replenishment operation subsequent to operation 515 of the fourth iteration of method 500 may prevent thickness loss of the gate spacer 635 and/or inner spacer 640 during subsequent operations. At operation 520 of the fourth iteration of method 500, method 500 may include providing a carbon-containing precursor to the processing region of the semiconductor processing chamber. Operation 520 of the fourth iteration of method 500 may be similar to and may include any features or characteristics as operation 520 of the first, second, and/or third iteration of method 500, and/or operation 315 previously discussed. At operation 525 of the fourth iteration of method 500, method 500 may include contacting the substrate 605 with the carbon-containing precursor. The contacting at operation 525 may replenish carbon in the gate spacer 635 and/or inner spacer 640. Operation 525 of the fourth iteration of method 500 may be similar to and may include any features or characteristics as operation 525 of the first, second, and/or third iteration of method 500 and/or operation 320 previously discussed. In embodiments, a pre-clean may be performed prior to operation 520 of the fourth iteration of method 500 to remove one or more residues from the gate spacer 635 that may limit effectiveness of the carbon replenishment operation.

Similar to the first, second, and/or third iteration of method 500 and to method 300, the fourth iteration of method 500 may include exposing the substrate 605 to UV radiation at optional operation 530. Optional operation 530 of the fourth iteration of method 500 may be similar to and may include any features or characteristics as operation 525 of the first, second, and/or third iteration of method 500 and/or operation 325 previously discussed.

At optional operation 535, the fourth iteration of method 500 may include providing a cleaning agent to the processing region of the semiconductor processing chamber. The cleaning agent may be any wet etchant and may be, for example, a fluorine-containing cleaning agent. In embodiments, the fluorine-containing cleaning agent may be or include dHF. The cleaning agent may also be a dry etchant, such as a fluorine-containing precursor that may be plasma-enhanced or not. Operation 535 of the fourth iteration of method 500 may be similar to and may include any features or characteristics as operation 535 of the first, second, and/or third iteration of method 500. At optional operation 540, the fourth iteration of method 500 may include contacting the substrate 605 with the cleaning agent. The cleaning agent may be provided to clean the structure 600 after the contacting at operation 525, which may leave a residue, such as an oxygen-containing material on one or more materials present on the substrate 605. Operation 540 of the fourth iteration of method 500 may be similar to and may include any features or characteristics as operation 540 of the first, second, and/or third iteration of method 500. Without performing the carbon replenishment, the carbon depleted material, such as the gate spacer 635 and/or inner spacer 640, may be etched at optional operation 535. However, the gate spacer 635 and/or inner spacer 640, after the carbon replenishment, may be more resistant to the cleaning at optional operations 535-540 and may not suffer from thickness loss during the cleaning.

The fourth iteration of method 500 may include performing post-cleaning operation(s) at optional operation 545.

The operations of method 500 may be repeated for a fifth iteration. The operations 505-540 of the fifth iteration of method 500 may be similar to and may include any features or characteristics as operation 505-540 as previously discussed with regard to the first, second, and/or third iteration of method 500. First, any pre-treatment operations may be performed at optional operation 505 of the third iteration of method 500. At operation 510 of the fifth iteration of method 500, one or more etchant precursors may be provided to the processing region of the semiconductor processing chamber. For example, the one or more etchant precursors may include a fluorine-containing precursor, a chlorine-containing precursor, an oxygen-containing precursor and/or an inert gas. In embodiments, the fifth iteration of method 500 may include forming a plasma of the one or more etchant precursors to increase bombardment and removal of material, such as the silicon-and-germanium-containing material 615 of the alternating layers.

At operation 515 of the fifth iteration of method 500, the substrate 605 may be contacted with the one or more etchant precursors. Method 500 may include etching a portion of the silicon-and-germanium-containing material 615 of the alternating layers from the substrate 605. As illustrated in FIG. 6I, the one or more etchant precursors may contact the substrate 605 and remove a portion of the silicon-and-germanium-containing material 615 of the alternating layers. The etching may remove the silicon-and-germanium-containing material 615 of the alternating layers entirely. Alternatively, some residue of the silicon-and-germanium-containing material 615 of the alternating layers may remain on the gate spacer 635. In embodiments, operation 515 of the fifth iteration of method 500 may be a channel release in GAA processing.

The etching at operation 515 of the fifth iteration of method 500 may deplete carbon from an exposed portion of the gate spacer 635 and/or the inner spacer 640. Accordingly, performing a fifth carbon replenishment operation subsequent to operation 515 of the fifth iteration of method 500 may prevent thickness loss of the gate spacer 635 and/or the inner spacer 640 during subsequent operations. At operation 520 of the fifth iteration of method 500, method 500 may include providing a carbon-containing precursor to the processing region of the semiconductor processing chamber. Operation 520 of the fifth iteration of method 500 may be similar to and may include any features or characteristics as operation 520 of the first, second, third and/or fourth iteration of method 500 and/or operation 315 previously discussed. At operation 525 of the fifth iteration of method 500, method 500 may include contacting the substrate 605 with the carbon-containing precursor. The contacting at operation 525 may replenish carbon in the gate spacer 635 and/or the inner spacer 640. Operation 525 of the fifth iteration of method 500 may be similar to and may include any features or characteristics as operation 525 of the first, second, third and/or fourth iteration of method 500 and/or operation 320 previously discussed. In embodiments, a pre-clean may be performed prior to operation 520 of the fifth iteration of method 500 to remove one or more residues from the gate spacer 635 that may limit effectiveness of the carbon replenishment operation.

Similar to the first, second, third and/or fourth iteration of method 500 and to method 300, the fifth iteration of method 500 may include exposing the substrate 605 to UV radiation at optional operation 530. Optional operation 530 of the fifth iteration of method 500 may be similar to and may include any features or characteristics as operation 525 of the first, second, third and/or fourth iteration of method 500 and/or operation 325 previously discussed.

At optional operation 535, the fifth iteration of method 500 may include providing a cleaning agent to the processing region of the semiconductor processing chamber. The cleaning agent may be any wet etchant and may be, for example, a fluorine-containing cleaning agent. In embodiments, the fluorine-containing cleaning agent may be or include dHF. The cleaning agent may also be a dry etchant, such as a fluorine-containing precursor that may be plasma-enhanced or not. Operation 535 of the fifth iteration of method 500 may be similar to and may include any features or characteristics as operation 535 of the first, second, third and/or fourth iteration of method 500. At optional operation 540, the fifth iteration of method 500 may include contacting the substrate 605 with the cleaning agent. The cleaning agent may be provided to clean the structure 600 after the contacting at operation 525, which may leave a residue, such as an oxygen-containing material on one or more materials present on the substrate 605. Operation 540 of the fifth iteration of method 500 may be similar to and may include any features or characteristics as operation 540 of the first, second, third and/or fourth iteration of method 500. Without performing the carbon replenishment, the carbon depleted material, such as the gate spacer 635 and/or inner spacer 640, may be etched at optional operation 535. However, the gate spacer 635 and/or inner spacer 640 after the carbon replenishment may be more resistant to the cleaning at optional operations 535-540 and may not suffer from thickness loss during the cleaning.

The fifth iteration of method 500 may include performing post-cleaning operation(s) at optional operation 545.

Subsequent contact application processing may include additional carbon replenishment operations. In conventional contact application processing, one skilled in the art would recognize the process flow may include multiple etching operations, such as material removal or hardmask patterning/stripping, that may deplete carbon from low-k materials. As such, the carbon replenishment, such as operations 520-530 of method 500 or method 300, during contact application processing.

For example, conventional contact application processing may include an etching operation to open holes or features in which contacts may be formed. Subsequent to this etching, a cleaning operation may be performed. However, carbon may be depleted from exposed materials, such as low-k materials including carbon. If left untreated, the cleaning operation may result in thickness loss of the carbon-depleted low-k material. Accordingly, the present technology may include a carbon replenishment operation subsequent to the etching operation to open holes or features in which contacts may be formed and prior to the cleaning operation.

Subsequent to the cleaning operation, PMOS patterning may be performed to allow for a subsequent P+ implant. In conventional contact application processing, another cleaning operation may follow the PMOS patterning, which again may result in thickness loss of carbon-depleted materials. Accordingly, the present technology may include a carbon replenishment operation subsequent to the PMOS patterning and prior to the cleaning operation.

After the P+ implant, the hardmask used for the PMOS patterning may be stripped and another cleaning operation may be performed. Again, thickness loss of carbon-depleted materials may result during this cleaning operation. However, the present technology may include a carbon replenishment operation subsequent to stripping hardmask used for the PMOS patterning and prior to the cleaning operation.

Subsequent to removing the hardmask for the PMOS patterning, a liner material, such as a low-k material, may be deposited in the holes or features in which contacts may be formed. An etch may be performed to remove a portion of the liner material. A cleaning operation subsequent to the etch to remove a portion of the liner material may result in thickness loss of carbon-depleted material. Again, the present technology may include a carbon replenishment operation subsequent to removing a portion of the liner material and prior to the cleaning operation.

The present technology may also include a carbon replenishment operation prior to forming contact metallization. In embodiments, the cleaning operation subsequent to removing a portion of the liner may be a wet clean that may deplete carbon from other regions of the substrate. A cleaning operation prior to forming contact metallization may be a dry clean that may result in thickness loss of the materials that may be carbon-depleted subsequent the wet clean. As such, the present technology may include a carbon replenishment operation subsequent to the wet clean operation performed after removing a portion of the liner material.

Process conditions may impact the operations performed in method 300. Each of the operations of method 300 may be performed during a constant temperature in embodiments, while in some embodiments the temperature may be adjusted during different operations. In some embodiments of the present technology, method 300 may be performed at substrate, pedestal, and/or chamber temperatures less or about 500° C., which may be due to thermal budget issues, and may be performed at temperatures less than or about 475° C., less than or about 450° C., less than or about 425° C., less than or about 400° C., less than or about 375° C., less or about 350° C., less or about 325° C., less or about 300° C., less or about 275° C., less or about 250° C., less or about 225° C., less or about 200° C., or lower. The temperature may also be maintained at any temperature within these ranges, within smaller ranges encompassed by these ranges, or between any of these ranges. Forming material at increased temperatures may increase the amount of carbon introduced into the silicon-containing material of the spacer 435 at operation 335 and, therefore, improve resistance to wet etchants. Accordingly, in some embodiments, the temperature may be maintained between at greater than or about 10° C., and may be maintained at greater than or about 25° C., greater than or about 50° C., greater than or about 75° C., greater than or about 100° C., greater than or about 125° C., greater than or about 150° C., greater than or about 175° C., greater than or about 200° C., greater than or about 225° C., greater than or about 250° C., greater than or about 275° C., greater than or about 300° C., greater than or about 325° C., greater than or about 350° C., or higher.

The pressure within the semiconductor processing chamber may also affect the operations performed. In embodiments, the pressure may be maintained at less than about 40 Torr. Accordingly, the pressure may be maintained at less than or about 35 Torr, less than or about 30 Torr, less than or about 25 Torr, less than or about 20 Torr, less than or about 18 Torr, less than or about 16 Torr, less than or about 14 Torr, less than or about 12 Torr, less than or about 10 Torr, less than or about 8 Torr, less than or about 6 Torr, less than or about 4 Torr, less than or about 2 Torr, less than or about 1 Torr, or less. The pressure may also be maintained at any pressure within these ranges, within smaller ranges encompassed by these ranges, or between any of these ranges.

In conventional embodiments, the remaining silicon-containing materials with reduced carbon concentration at the exposed surface of the silicon-containing materials, may have poor resistance to the cleaning agents, such as fluorine-containing species. In these conventional embodiments, silicon-containing materials may be removed entirely, which may damage or destroy the structure. By treating the silicon-containing materials with the carbon-containing precursors and/or exposing the silicon-containing materials to UV radiation, carbon may be replenished to the silicon-containing materials. The increased carbon concentration may increase the resistance of the silicon-containing materials to cleaning agents and other etchants used in processing. Conventional embodiments may immediately begin etching the silicon-containing materials when exposed to cleaning agents and other wet etchants whereas the present technology may resist any etching for greater than or about 5 seconds of exposure, such as greater than 10 seconds of exposure, greater than or about 15 seconds of exposure, greater than 20 seconds of exposure, greater than or about 25 seconds of exposure, greater than 30 seconds of exposure, greater than or about 35 seconds of exposure, greater than 40 seconds of exposure, or more.

In embodiments, operations 305-335 of method 300 and operations 505-555 of method 500, including multiple iterations, may be performed on a single mainframe or processing system, such as processing system 100 shown in FIG. 1. Accordingly, operations of method 300 and method 500 may be performed without breaking vacuum and without exposure to ambient conditions. By maintaining vacuum, queue times may be reduced, and throughput may be increased. However, it is also contemplated that vacuum may be broken between operations, such as between operation 310 and 315 or between operations 515 and 520 for example. For example, when operation 310 or 515 includes a wet etch operation using dHF, vacuum may be broken.

As previously discussed, the processing system, such as processing system 100, may be configured to perform some or all of operations 305-335 of method 300 and operations 505-555 of method 500 previously discussed. For example, one embodiment of a processing system, which may also be referred to as a cluster tool, may include a first semiconductor processing chamber for performing operations 305 and 310 (or operations 510 and 515) to etch a portion of a layer of material. After etching a portion of the layer of material, the substrate 405 may be transferred to a second semiconductor processing chamber. The second semiconductor processing chamber may be on the same mainframe as the first semiconductor processing chamber. Accordingly, vacuum may be maintained during transfer between the first semiconductor processing chamber and the second semiconductor processing chamber. The second semiconductor processing chamber may perform operations 315 and 320 (or operations 520 and 525) to introduce carbon that was depleted during earlier etching.

Another embodiment of a processing system or cluster tool may include a third semiconductor processing chamber that may be able to perform operations 330 and 335 (or operations 535-545) after operation 325 (or operation 530) is performed in the second semiconductor processing chamber. Yet another embodiment of a processing system or cluster tool may include one or more pre-treatment semiconductor processing chambers, in addition to the first semiconductor processing chamber and the second semiconductor processing chamber discussed previously, able to perform operations before method 300 or method 500. For example, the additional one or more pre-treatment semiconductor processing chambers may include a single chamber operable to perform operation 505. Still yet another embodiment of a processing system or cluster tool may include each of the semiconductor processing chambers previously discussed operable to perform all of operations 305-335 or operations 505-545. While it is contemplated that any number of operations may be combined in a single semiconductor processing chamber, each operation may also be performed in a separate semiconductor processing chamber.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursor, and reference to “the material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing an etchant precursor to a processing region of a semiconductor processing chamber, wherein a structure is disposed within the processing region, wherein the structure comprises a first silicon-containing material, and wherein the structure comprises a second silicon-containing material, an oxygen-containing material, or both;
contacting the structure with the etchant precursor, wherein the contacting with the etchant precursor etches at least a portion of the second silicon-containing material or the oxygen-containing material from the structure;
providing a carbon-containing precursor to the processing region of the semiconductor processing chamber; and
contacting the structure with the carbon-containing precursor, wherein the contacting with the carbon-containing precursor replenishes carbon in the first silicon-containing material.

2. The semiconductor processing method of claim 1, wherein the second silicon-containing material comprises a silicon-and-oxygen-containing material or a silicon-and-germanium-containing material.

3. The semiconductor processing method of claim 1, wherein the first silicon-containing material comprises a silicon-and-carbon-containing material.

4. The semiconductor processing method of claim 1, wherein the etchant precursor comprises a halogen-containing precursor.

5. The semiconductor processing method of claim 1, wherein contacting the structure with the carbon-containing precursor increases carbon in the first silicon-containing material by greater than or about 0.1 at. %.

6. The semiconductor processing method of claim 1, wherein the carbon-containing precursor comprises hexamethyldisilazane (HMDS), tetramethyldisilazane (TMDS), trimethylchlorosilane (TMCS), dimethyldichlorosilane (DMDCS), methyltrichlorosilane (MTCS), trimethylmethoxysilane (TMMS) (CH₃—O—Si—(CH₃)₃), dimethyldimethoxysilane (DMDMS) ((CH₃)₂—Si—(OCH₃)₂), methyltrimethoxysilane (MTMS) ((CH₃—O)₃—Si—CH₃), phenyltrimethoxysilane (PTMOS) (C₆H₅—Si—(OCH₃)₃), phenyldimethylchlorosilane (PDMCS) (C₆H₅—Si(Cl)—(CH₃)₂), dimethylaminotrimethylsilane (DMATMS) ((CH₃)₂—N—Si—(CH₃)₃), or bis(dimethylamino)dimethylsilane (BDMADMS).

7. The semiconductor processing method of claim 1, further comprising:
exposing the structure to ultraviolet (UV) radiation while contacting the structure with the carbon-containing precursor or subsequent to contacting the structure with the carbon-containing precursor.

8. The semiconductor processing method of claim 7, wherein contacting the structure with the carbon-containing precursor and exposing the structure to ultraviolet (UV) radiation are performed simultaneously.

9. The semiconductor processing method claim 1, further comprising:
subsequent to contacting the structure with the carbon-containing precursor, providing a cleaning agent to the processing region of the semiconductor processing chamber; and
contacting the structure with the cleaning agent, wherein the contacting with the cleaning agent removes a residue from the structure.

10. The semiconductor processing method claim 1, wherein a temperature in the semiconductor processing chamber is less than or about 500° C.

11. A semiconductor processing method comprising:
providing a first etchant precursor to a processing region of a semiconductor processing chamber, wherein a structure is disposed within the processing region, wherein the structure comprises alternating layers of a first silicon-containing material and a silicon-and-germanium-containing material, and wherein the structure comprises a second silicon-containing material overlying and extending into one or more recesses defined by the alternating layers of the first silicon-containing material and the silicon-and-germanium-containing material;
contacting the structure with the first etchant precursor, wherein the contacting with the first etchant precursor etches through the alternating layers of the first silicon-containing material and the silicon-and-germanium-containing material;
providing a first carbon-containing precursor to the processing region of the semiconductor processing chamber;
contacting the structure with the first carbon-containing precursor, wherein the contacting with the first carbon-containing precursor replenishes carbon in the second silicon-containing material;
providing a first cleaning agent to the processing region of the semiconductor processing chamber;
contacting the structure with the first cleaning agent, wherein the contacting with the first cleaning agent removes a first residue from the structure;
providing a second etchant precursor to the processing region of the semiconductor processing chamber;
contacting the structure with the second etchant precursor, wherein the contacting etches a portion of the silicon-and-germanium-containing material;
providing a silicon-containing precursor to the processing region;
contacting the structure with the silicon-containing precursor, wherein the contacting deposits a third silicon-containing material on the structure, and wherein the third silicon-containing material extends into recesses defined by the etched portion of the silicon-and-germanium-containing material;
providing a third etchant precursor to the processing region of the semiconductor processing chamber;
contacting the structure with the third etchant precursor, wherein the contacting etches a portion of the third silicon-containing material, and wherein, subsequent to the contacting, the third silicon-containing material remaining extends into recesses defined by the etched portion of the silicon-and-germanium-containing material;
providing a second carbon-containing precursor to the processing region of the semiconductor processing chamber;
contacting the structure with the second carbon-containing precursor, wherein the contacting with the second carbon-containing precursor replenishes carbon in the third silicon-containing material;
providing a second cleaning agent to the processing region of the semiconductor processing chamber;
contacting the structure with the second cleaning agent, wherein the contacting with the second cleaning agent removes a second residue from the structure;
providing a fourth etchant precursor to the processing region of the semiconductor processing chamber;
contacting the structure with the fourth etchant precursor, wherein the contacting with the fourth etchant precursor removes a dummy oxide material from the structure;
providing a third carbon-containing precursor to the processing region of the semiconductor processing chamber;
contacting the structure with the third carbon-containing precursor, wherein the contacting with the third carbon-containing precursor replenishes carbon in the second silicon-containing material;
providing a fifth etchant precursor to the processing region of the semiconductor processing chamber;
contacting the structure with the fifth etchant precursor, wherein the contacting with the fifth etchant precursor removes the silicon-and-germanium-containing material from the structure;
providing a fourth carbon-containing precursor to the processing region of the semiconductor processing chamber; and
contacting the structure with the fourth carbon-containing precursor, wherein the contacting with the fourth carbon-containing precursor replenishes carbon in the second silicon-containing material, the third silicon-containing material, or both.

12. The semiconductor processing method of claim 11, wherein one or more of the first carbon-containing precursor, the second carbon-containing precursor, the third carbon-containing precursor, and the fourth carbon-containing precursor are the same carbon-containing precursor.

13. The semiconductor processing method of claim 11, wherein the second silicon-containing material, the third silicon-containing material, or both are characterized by a dielectric constant of less than or about 7.5.

14. The semiconductor processing method of claim 11, wherein contacting the structure with the first carbon-containing precursor, the second carbon-containing precursor, the third carbon-containing precursor, or the fourth carbon-containing precursor prevents thickness loss of the second silicon-containing material, the third silicon-containing material, or both during subsequent operations.

15. The semiconductor processing method of claim 11, wherein one or more of the first etchant precursor, the second etchant precursor, the third etchant precursor, or the fourth etchant precursor comprises a hydrogen-containing precursor, a nitrogen-containing precursor, a helium-containing precursor, a halogen-containing precursor, or an oxygen-containing precursor.

16. The semiconductor processing method of claim 11, further comprising:
depositing an epitaxial material on the structure prior to contacting the structure with the fourth etchant precursor.

17. A semiconductor processing system comprising:
a first semiconductor processing chamber, wherein the first semiconductor processing chamber is configured to:
flow an etchant precursor to a processing region of the first semiconductor processing chamber, wherein a structure is disposed within the processing region, wherein the structure comprises a first silicon-containing material, and wherein the structure comprises a second silicon-containing material, an oxygen-containing material, or both; and
contact the structure with the etchant precursor, wherein the contacting with the etchant precursor etches at least a portion of the second silicon-containing material or the oxygen-containing material from the structure; and
a second semiconductor processing chamber on the same mainframe as the first semiconductor processing chamber, wherein the second semiconductor processing chamber is configured to:
flow a carbon-containing precursor to a processing region of the second semiconductor processing chamber; and
contact the structure with the carbon-containing precursor, wherein the contacting with the carbon-containing precursor replenishes carbon in the first silicon-containing material.

18. The semiconductor processing system of claim 17, further comprising:
a third semiconductor processing chamber on the same mainframe as the first semiconductor processing chamber and the second semiconductor processing chamber, wherein the third semiconductor processing chamber is configured to:
flow a cleaning agent to a processing region of the third semiconductor processing chamber; and
contact the structure with the cleaning agent, wherein contacting with the cleaning agent removes a residue from the structure.

19. The semiconductor processing system of claim 18, further comprising:
a fourth semiconductor processing chamber on the same mainframe as the first semiconductor processing chamber, the second semiconductor processing chamber, and the third semiconductor processing chamber, wherein the fourth semiconductor processing chamber is configured to:
flow one or more deposition gases to a processing region of the fourth semiconductor processing chamber; and
contact the structure with the one or more deposition gases, wherein contacting with the one or more deposition gases deposits an epitaxial material on the structure.

20. The semiconductor processing system of claim 17, further comprising:
one or more pre-treatment semiconductor processing chambers on the same mainframe as the first semiconductor processing chamber and the second semiconductor processing chamber, wherein the one or more pre-treatment semiconductor processing chambers are configured to:
etch a portion of the first silicon-containing material and the silicon-and-germanium-containing material;
deposit the second silicon-containing material on the structure; and/or
etch a portion of the second silicon-containing material.
